(19) United States
(12) Patent Application Publication
(10) Pub. No.: US 2018/0351579 A1
(43) Pub. Date: Dec. 6, 2018

(54) WTRU IDENTIFICATION USING POLAR CODE FROZEN BITS

(71) Applicant: IDAC HOLDINGS, INC., Wilmington, DE (US)

(72) Inventors: Sungkwon Hong, Dongjak-gu, Seoul (KR); Jaehyun Ahn, Eunpyeong-gu, Seoul (KR)

(73) Assignee: IDAC HOLDINGS, INC., Wilmington, DE (US)

(21) Appl. No.: 15/780,467

(22) PCT Filed: Dec. 14, 2016
(86) PCT No.: PCT/US2016/066489

§ 371 Date: May 31, 2018

Related U.S. Application Data
(60) Provisional application No. 62/266,975, filed on Dec. 14, 2015.

(51) Int. Cl. H03M 13/13; H04L 1/00; H04W 8/28; H04W 8/18

(52) U.S. Cl. CPC H03M 13/13; H04L 1/0057; H04W 76/11; H04W 8/28; H04W 8/186; H04L 1/0041

(57) ABSTRACT

A method and apparatus for transmitting a polar coded transport block is disclosed. A position of a frozen bit of a polar code may be determined. A value for the frozen bit may be determined. The value for the frozen bit may be based on a wireless transmit/receive unit's (WTRU's) identity (ID). A polar coded transport block may be transmitted to the WTRU that includes the frozen bit value that is based on the WTRU's ID.

### CROSS REFERENCE TO RELATED APPLICATIONS

This application claims the benefit of U.S. Provisional Application Ser. No. 62/266,975 filed on Dec. 14, 2015, the contents of which is hereby incorporated by reference herein.

### BACKGROUND

Polar codes have been developed and introduced by Erdal Arikan. A typical polar code is defined as: x₀^{N-1}=u₀^{N-1}G_{N} where uₒ^{N-1} is a vector of an input code block and x₀^{N-1} is a vector of an output code block. Both the input block vector and the output block vector have the same length N, indexed from 0 to N−1, where N=2ⁿ. The number of information bits with variable binary values may be represented by K. The positions of information bits with variable binary values may be represented by a set A. Some bits in the input block may be set to a fixed or frozen value, which is usually 0. The number of bits with a frozen value may be N−K. The positions of bits with a frozen value may be represented by a set A^{c}. A code rate may be represented by R=N/K.

G_{N} is a generator matrix and may be further expressed as G_{N}=B_{N}F^{⊗n}. B_{N} is a bit reversing matrix and a bit reversing operation for the input block vector may be performed by a product operation. For example, “001” may be transformed to “100” after bit reversing. F^{⊗n} is a n^{th} kronecker product of F and maybe defined as shown in Equation 1.

$$F = [ \begin{matrix}1 & 0 \\ 1 & 1\end{matrix} ] , {F}^{⊗ 2} = F ⊗ F = [ \begin{matrix}F & 0 \\ F & F\end{matrix} ] = [ \begin{matrix}1 & 0 & 0 & 0 \\ 1 & 1 & 0 & 0 \\ 1 & 0 & 1 & 0 \\ 1 & 1 & 1 & 1\end{matrix} ] \qquad Equation 1$$

### SUMMARY

A method and apparatus for transmitting a polar coded transport block is disclosed. A position of a frozen bit of a polar code may be determined. A value for the frozen bit may be determined. The value for the frozen bit may be based on a wireless transmit/receive unit's (WTRU's) identity (ID). A polar coded transport block may be transmitted to the WTRU that includes the frozen bit value that is based on the WTRU's ID.

A position for a frozen bit of a polar code may be determined. A control format may be determined. A value for the frozen bit may be determined. The value for the frozen bit may be a function of the determined control format. A polar coded message may be transmitted including control format information using the determined frozen bit value.

### BRIEF DESCRIPTION OF THE DRAWINGS

A more detailed understanding may be had from the following description, given by way of example in conjunction with the accompanying drawings wherein:

FIG. 1A is a system diagram of an example communications system in which one or more disclosed embodiments may be implemented;

FIG. 1B is a system diagram of an example wireless transmit/receive unit (WTRU) that may be used within the communications system illustrated in FIG. 1A;

FIG. 1C is a system diagram of an example radio access network and an example core network that may be used within the communications system illustrated in FIG. 1A;

FIG. 2 is an example of a polar encoder;

FIG. 3 is an example showing a numerical result for a polar code;

FIG. 4 is a graph which illustrates a frame error rate (FER) performance of polar codes;

FIG. 5 shows an example method of identifying a control format using a frozen bit of a polar code;

FIG. 6 shows an example method of identifying a WTRU using a frozen bit of a polar code;

FIG. 7 is a graph which illustrates FER comparisons between zero valued frozen bits and random valued frozen bits;

FIG. 8 is a graph which illustrates reliabilities of input bits of a polar code;

FIG. 9 shows an example method of using reliable blocks of a polar coded transport block to assign cyclic redundancy check (CRC) bits;

FIG. 10 is graph which illustrates FER comparisons where R=½, K=88, and 80 bits are punctured;

FIG. 11 is a graph which illustrates a distribution of reliabilities of polar codes;

FIG. 12 shows an example method of puncturing for low code rate polar codes;

FIG. 13 is a graph which illustrates fixed values of input bits of a polar code; and

FIG. 14 is a graph which illustrates FER performance comparisons.

### DETAILED DESCRIPTION

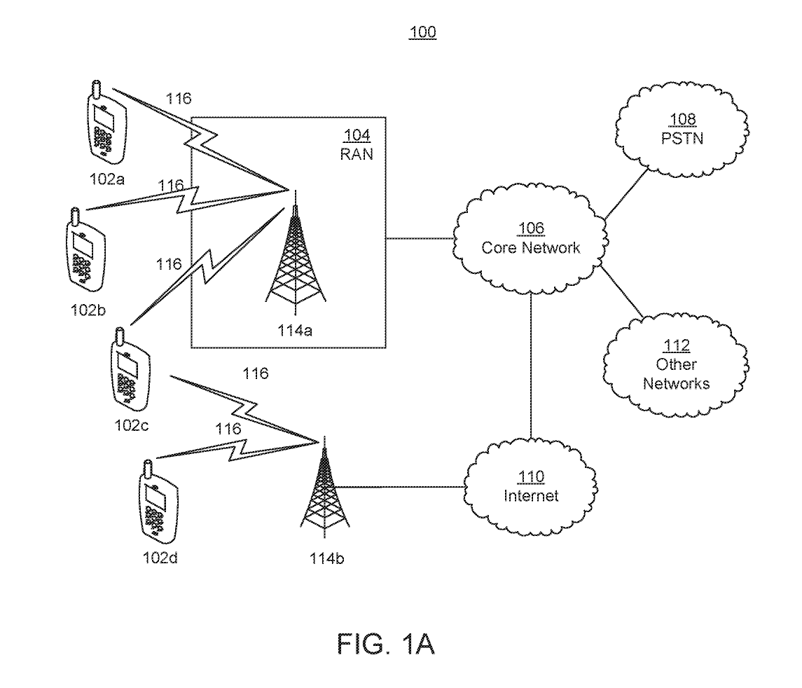

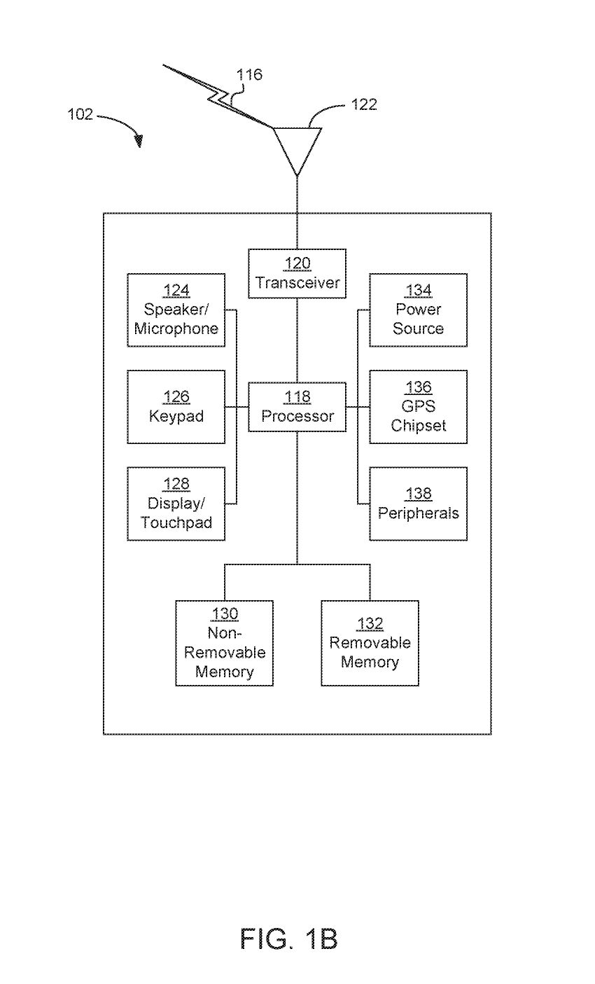

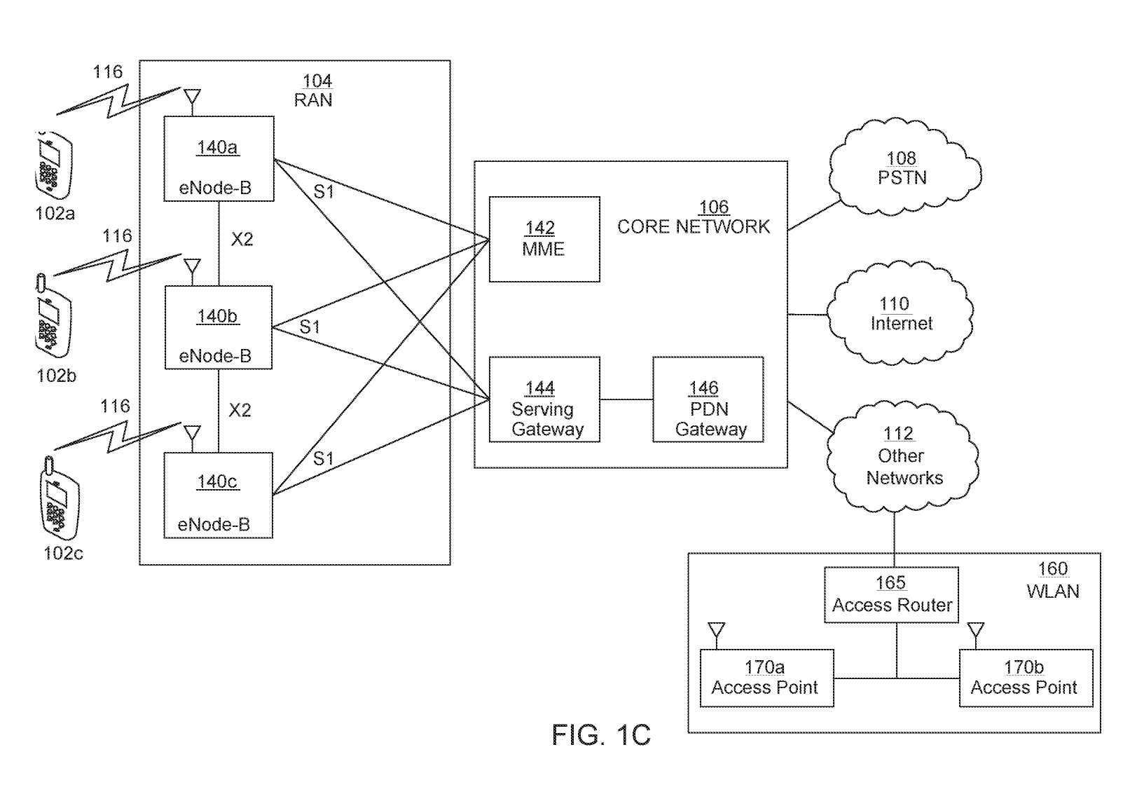

FIG. 1A is a diagram of an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), and the like.

As shown in FIG. 1A, the communications system 100 may include wireless transmit/receive units (WTRUs) 102a, 102b, 102c, 102d, a radio access network (RAN) 104, a core network 106, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d may be configured to transmit and/or receive wireless signals and may include user equipment (UE), a mobile station, a fixed or mobile subscriber unit, a pager, a cellular telephone, a personal digital assistant (PDA), a smartphone, a laptop, a netbook, a personal computer, a wireless sensor, consumer electronics, and the like.

The communications systems 100 may also include a base station 114a and a base station 114b. Each of the base stations 114a, 114b may be any type of device configured to wirelessly interface with at least one of the WTRUs 102a, 102b, 102c, 102d to facilitate access to one or more communication networks, such as the core network 106, the Internet 110, and/or the other networks 112. By way of example, the base stations 114a, 114b may be a base transceiver station (BTS), a Node-B, an eNode B, a Home Node B, a Home eNode B, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104, which may also include other base stations and/or network elements (not shown), such as a base station controller (BSC), a radio network controller (RNC), relay nodes, etc. The base station 114a and/or the base station 114b may be configured to transmit and/or receive wireless signals within a particular geographic region, which may be referred to as a cell (not shown). The cell may further be divided into cell sectors. For example, the cell associated with the base station 114a may be divided into three sectors. Thus, in one embodiment, the base station 114a may include three transceivers, i.e., one for each sector of the cell. In another embodiment, the base station 114a may employ multiple-input multiple-output (MIMO) technology and, therefore, may utilize multiple transceivers for each sector of the cell.

The base stations 114a, 114b may communicate with one or more of the WTRUs 102a, 102b, 102c, 102d over an air interface 116, which may be any suitable wireless communication link (e.g., radio frequency (RF), microwave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104 and the WTRUs 102a, 102b, 102c may implement a radio technology such as Universal Mobile Telecommunications System (UMTS) Terrestrial Radio Access (UTRA), which may establish the air interface 116 using wideband CDMA (WCDMA). WCDMA may include communication protocols such as High-Speed Packet Access (HSPA) and/or Evolved HSPA (HSPA+). HSPA may include High-Speed Downlink Packet Access (HSDPA) and/or High-Speed Uplink Packet Access (HSUPA).

In another embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A).

In other embodiments, the base station 114a and the WTRUs 102a, 102b, 102c may implement radio technologies such as IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, and the like. In one embodiment, the base station 114b and the WTRUs 102c, 102d may implement a radio technology such as IEEE 802.11 to establish a wireless local area network (WLAN). In another embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, etc.) to establish a picocell or femtocell. As shown in FIG. 1A, the base station 114b may have a direct connection to the Internet 110. Thus, the base station 114b may not be required to access the Internet 110 via the core network 106.

The RAN 104 may be in communication with the core network 106, which may be any type of network configured to provide voice, data, applications, and/or voice over internet protocol (VoIP) services to one or more of the WTRUs 102a, 102b, 102c, 102d. For example, the core network 106 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104 and/or the core network 106 may be in direct or indirect communication with other RANs that employ the same RAT as the RAN 104 or a different RAT. For example, in addition to being connected to the RAN 104, which may be utilizing an E-UTRA radio technology, the core network 106 may also be in communication with another RAN (not shown) employing a GSM radio technology.

The core network 106 may also serve as a gateway for the WTRUs 102a, 102b, 102c, 102d to access the PSTN 108, the Internet 110, and/or other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and the internet protocol (IP) in the TCP/IP internet protocol suite. The networks 112 may include wired or wireless communications networks owned and/or operated by other service providers. For example, the networks 112 may include another core network connected to one or more RANs, which may employ the same RAT as the RAN 104 or a different RAT.

Some or all of the WTRUs 102a, 102b, 102c, 102d in the communications system 100 may include multi-mode capabilities, i.e., the WTRUs 102a, 102b, 102c, 102d may include multiple transceivers for communicating with different wireless networks over different wireless links. For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram of an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and other peripherals 138. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Array (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In another embodiment, the transmit/receive element 122 may be an emitter/detector configured to transmit and/or receive IR, UV, or visible light signals, for example. In yet another embodiment, the transmit/receive element 122 may be configured to transmit and receive both RF and light signals. It will be appreciated that the transmit/receive element 122 may be configured to transmit and/or receive any combination of wireless signals.

In addition, although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as UTRA and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NIMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs or video), a universal serial bus (USB) port, a vibration device, a television transceiver, a hands free headset, a Bluetooth® module, a frequency modulated (FM) radio unit, a digital music player, a media player, a video game player module, an Internet browser, and the like.

FIG. 1C is a system diagram of the RAN 104 and the core network 106 according to an embodiment. As noted above, the RAN 104 may employ an E-UTRA radio technology to communicate with the WTRUs 102a, 102b, 102c over the air interface 116. The RAN 104 may also be in communication with the core network 106.

The RAN 104 may include eNode-Bs 140a, 140b, 140c, though it will be appreciated that the RAN 104 may include any number of eNode-Bs while remaining consistent with an embodiment. The eNode-Bs 140a, 140b, 140c may each include one or more transceivers for communicating with the WTRUs 102a, 102b, 102c over the air interface 116. In one embodiment, the eNode-Bs 140a, 140b, 140c may implement MIMO technology. Thus, the eNode-B 140a, for example, may use multiple antennas to transmit wireless signals to, and receive wireless signals from, the WTRU 102a.

Each of the eNode-Bs 140a, 140b, 140c may be associated with a particular cell (not shown) and may be configured to handle radio resource management decisions, handover decisions, scheduling of users in the uplink and/or downlink, and the like. As shown in FIG. 1C, the eNode-Bs 140a, 140b, 140c may communicate with one another over an X2 interface.

The core network 106 shown in FIG. 1C may include a mobility management entity gateway (MME) 142, a serving gateway 144, and a packet data network (PDN) gateway 146. While each of the foregoing elements are depicted as part of the core network 106, it will be appreciated that any one of these elements may be owned and/or operated by an entity other than the core network operator.

The MME 142 may be connected to each of the eNode-Bs 140a, 140b, 140c in the RAN 104 via an S1 interface and may serve as a control node. For example, the MME 142 may be responsible for authenticating users of the WTRUs 102a, 102b, 102c, bearer activation/deactivation, selecting a particular serving gateway during an initial attach of the WTRUs 102a, 102b, 102c, and the like. The MME 142 may also provide a control plane function for switching between the RAN 104 and other RANs (not shown) that employ other radio technologies, such as GSM or WCDMA.

The serving gateway 144 may be connected to each of the eNode Bs 140a, 140b, 140c in the RAN 104 via the S1 interface. The serving gateway 144 may generally route and forward user data packets to/from the WTRUs 102a, 102b, 102c. The serving gateway 144 may also perform other functions, such as anchoring user planes during inter-eNode B handovers, triggering paging when downlink data is available for the WTRUs 102a, 102b, 102c, managing and storing contexts of the WTRUs 102a, 102b, 102c, and the like.

The serving gateway 144 may also be connected to the PDN gateway 146, which may provide the WTRUs 102a, 102b, 102c with access to packet-switched networks, such as the Internet 110, to facilitate communications between the WTRUs 102a, 102b, 102c and IP-enabled devices.

The core network 106 may facilitate communications with other networks. For example, the core network 106 may provide the WTRUs 102a, 102b, 102c with access to circuit-switched networks, such as the PSTN 108, to facilitate communications between the WTRUs 102a, 102b, 102c and traditional land-line communications devices. For example, the core network 106 may include, or may communicate with, an IP gateway (e.g., an IP multimedia subsystem (IMS) server) that serves as an interface between the core network 106 and the PSTN 108. In addition, the core network 106 may provide the WTRUs 102a, 102b, 102c with access to the networks 112, which may include other wired or wireless networks that are owned and/or operated by other service providers.

Other network 112 may further be connected to an IEEE 802.11 based wireless local area network (WLAN) 160. The WLAN 160 may include an access router 165. The access router may contain gateway functionality. The access router 165 may be in communication with a plurality of access points (APs) 170a, 170b. The communication between access router 165 and APs 170a, 170b may be via wired Ethernet (IEEE 802.3 standards), or any type of wireless communication protocol. AP 170a is in wireless communication over an air interface with WTRU 102d.

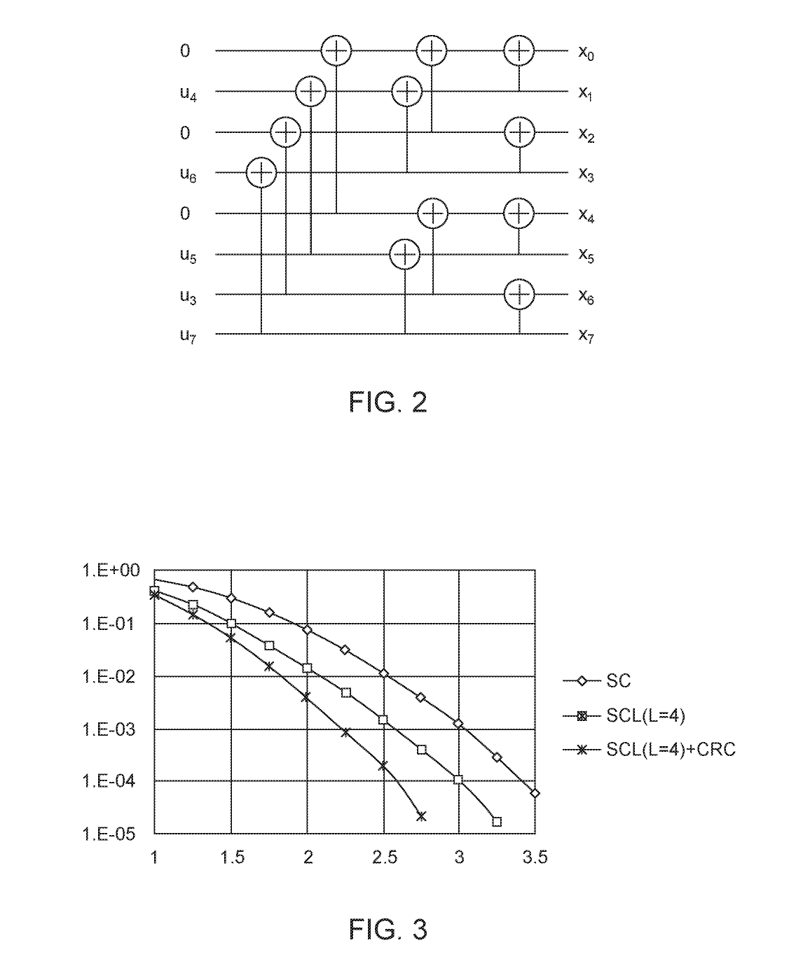

An example of a polar encoder is shown in FIG. 2. In this example, the parameters for a polar code are (N,K,A)=(8,5,{3,4,5,6,7}). Five bits, u₄,u₆,u₅,u₃,u₇, are input and the index order of the input bit sequence is changed by a bit reversing operation from {3,4,5,6,7} to {6,1,5,3,7}. Eight bits, x₀, x₁, . . . , x₇, are output from the polar encoder. The set A may be referred to as unfrozen bits and the set A^{c} may be referred to as frozen bits. Since A={3,4,5,6,7}, bit positions of A^{c}={0,1,2} have a frozen value of 0. The code rate is R=N/K=⅝.

Determining the positions of the frozen bits may be performed using a code construction of a polar code. An order of reliability may be determined for the input bits. The least reliable N−K bits of the input bits may be selected as frozen bits.

There are several methods for polar code construction. One method for polar code construction is the Bhattacharyya bounds code construction. The Bhattacharyya bounds code construction is a simple method but is less accurate than other methods. It shows a good performance for a medium size N, which may be in the range of several thousand. Below is an example pseudo-code of a Bhattacharyya bounds code construction.

```
INPUT: N, K, and design-SNR EdB = (RE_{b}/Nₒ in dB)
OUTPUT: [symbol]    ⊂ {0, 1, . . . , N − 1} with | [symbol]   | = N − K
  1: S = 10^{EdB/10} and n = log₂N
  2: z⁽⁰⁾ ϵ [symbol] ^{N}, initialize z⁽⁰⁾[0] = exp(−S)
  3: for j = 1: n do
  4: | u = 2^{j}
  5: |  $for t = 0 \text{:} \frac{u}{2} - 1 do ⊳ For each connection$
  6: | | T = z⁽⁰⁾[t]
  7: | | z⁽⁰⁾[t] = 2T − T² [symbol]   Upper channel
  8: | | z⁽⁰⁾[ u/2 + t] = T² [symbol]   Lower channel
  9: | end
10: end
11: [symbol]   = indices_of_greatest_elements (z⁽⁰⁾, N − K)
  // Find indices of the greatest N − K elements
12: Return [symbol]
```

With reference to the pseudo-code above, the design signal-to-noise ratio (SNR) is an assumed SNR of output bits. F is a set of positions for frozen bits A^{c}.

There are several decoding algorithms available for polar codes. One decoding algorithm is called successive cancellation (SC). Bits u₀, . . . , uₖ₋₁ before uₖ are assumed to be correctly decoded. log N+1 layers and N nodes for each layer may be implemented for SC decoding. From bits u₀ to u_{N-1}, SC recursively calculates a likelihood probability of nodes by predefined algorithmic combinations and order from the previously calculated likelihood values of nodes. For calculations of a likelihood probability, an F operation and G operation may be performed. SC complexity is proportional to N log N.

SC list (SCL) decoding may be done with or without usage of a cyclic redundancy check (CRC). For SCL decoding without using a CRC, an SCL decoder may track L paths. The most probable L paths may be kept before a final decision of decoding input bits. The most probable decoded sequence in SCL decoding without a CRC is selected. For SCL decoding, a CRC may be used for selecting a candidate. Concatenation of a CRC may be added as the outer block code. Selection may be made by CRC checking when a CRC is added. Among L paths, the path which has no error detection in the CRC calculation may be selected for decoding instead of selecting the most probable path. Complexity of SCL decoding is proportional to LN log N.

FIG. 3 shows an example of a numerical result for a polar code. The conditions for this example are: (N,K,A)=(1024,512,A); code rate R=½; code block size=1024 bit; binary phase-shift keying (BPSK); additive white gaussian noise (AWGN); SCL+CRC decoder; L=4; 24 bit CRC; Bhattacharyya bounds code construction; design SNR=0 dB; x axis is Eb/N0 (dB); y axis is frame error rate (FER).

When a polar decoder does not know the values of frozen bits, the polar decoder cannot decode the inputs correctly. This property may be used for security applications. For example, if an eavesdropper does not know the values of frozen bits, the eavesdropper cannot decode the inputs and needs to try to decode all possible values of the frozen bits.

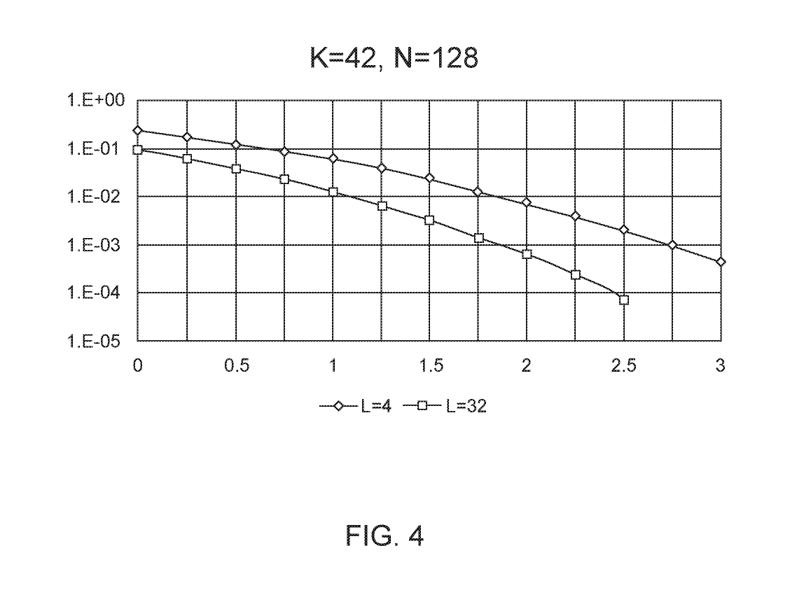

Polar codes may be a candidate for channel coding of fifth generation cellular systems and are expected to be used for short packet sizes as well as large packet sizes. Polar codes may provide further performance improvement by increasing the length L value at the expense of increasing complexity. FIG. 4 shows a performance of a polar code in the case of length L=4 and L=32. Polar coding may achieve a target frame error rate (FER) of 10⁻² at E_{b}/N₀ of less than 2 dB when L=4. This performance is superior to tail-biting convolution coding currently used for the physical downlink control channel (PDCCH) in a 3GPP LTE system.

The complexity of polar decoding with L=4 and using an SCL decoding algorithm may be comparable to tail-biting convolution decoding with a constraint length of 7. Some complexities of polar codes and tail-biting convolution codes are as follows: for polar codes: N log(N)=128×4×log(128)=3584; for tail-biting convolution codes: 64×1×42×2=5376; for tail-biting convolution codes, one metric update, two iterations, and the same decoding depth(=42) as input information bits are assumed.

In a 3GPP LTE system, a PDCCH is used to convey control information such as resource allocation information, hybrid automatic repeat request (HARQ) process information, and modulation and coding scheme (MCS) information. Blind decoding is required to acquire control information from a PDCCH and a WTRU attempts to decode possible PDCCH candidates blindly in a predefined position of a common or a WTRU-specific search space. The maximum number of blind decoding attempts in 3GPP LTE Release 8 is 44. The channel code used for a PDCCH is a tail-biting convolution code of constraint length 7 and the target FER for a PDCCH is 10⁻².

A consideration in designing a PDCCH is an insertion of zero padding bits to differentiate downlink control information (DCI) formats from each other. For example, the size of DCI format 0/1A may be the same size as DCI format 1 for some bandwidth and may cause confusion in differentiating between the two formats. Zero padding bits may be inserted into a DCI format 1 until the size may be differentiated from the DCI format 0/1A.

As new features are added to LTE specifications, new control information may be added to PDCCH DCI formats and the use of zero padding bits may be considered for each update.

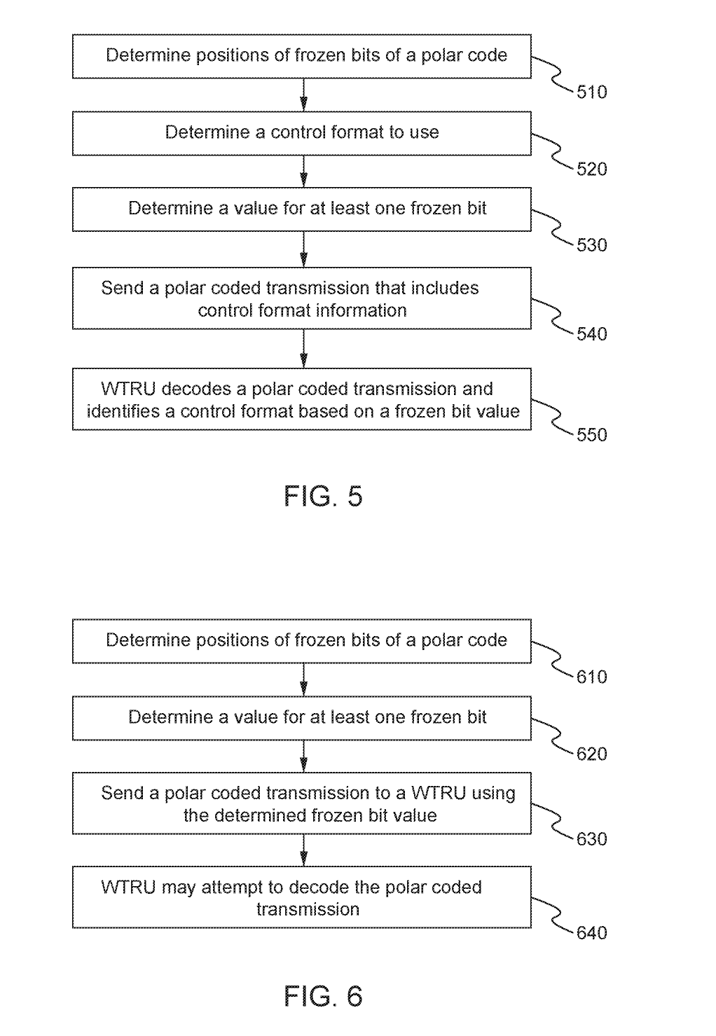

FIG. 5 shows an example method of identifying a control format using a frozen bit of a polar code. A base station may determine the positions of frozen bits of a polar code 510. The positions of frozen bits may be determined, for example, from the process of polar code construction. The frozen bit positions may be referred to as fₖ where (k=0, 1, . . . , N−K−1). The frozen bit positions may be saved in a memory. The base station may determine the frozen bit positions by accessing the memory to retrieve the frozen bit positions.

The base station may determine a control format to use 520. The control format may be determined during scheduling of downlink and uplink resources and delivering control information.

The base station may determine a value for at least one frozen bit 530. Frozen bit values may be referred to as vₖ where (k=0, 1, . . . , N−K−1). The frozen bits values may be defined as vₖ=c_{i,k}.

The value of i may be a function of a control format. A different frozen bit value may be used for each control format to differentiate between control formats. For example, c_{i,k} may be the i^{th} codeword for various codes maximizing Hamming distance among c_{i,k}, for example, a Walsh-Hadamard code. In a 3GPP LTE example, for a DCI format 0/1A, i=0, c_{0,k=0, . . . m}=1, 1, . . . , 1, 1, and for a DCI format 1, i=1, c_{1,k=0, . . . m}=0, 1, 0, 1, . . . , 0, 1. In another example, c_{i,k} may be a pseudo-random sequence, for example, a pseudo noise (PN) sequence. For a DCI format 0/1A, i=0, initialized by 1 and for a DCI format 1, i=1, initialized by 2.

The identifications or values for each control format may be predefined and a base station and WTRU may know or be configured with the control format identifications or values. The base station may use a predefined value or identification for the determined control format as a frozen bit value. Therefore, a frozen bit value may correspond to a particular control format.

The base station may send a polar coded transmission to a WTRU that includes control format information 540. The WTRU may decode the polar coded transmission and identify a control format based on a frozen bit value 550. The WTRU may try all possible decoding of a control format with corresponding frozen bit values. If the WTRU successfully decodes a frozen bit value, for example by a CRC check, the WTRU may identify the control format.

If the size of the frozen bits and c_{i,k} are different, c_{i,k} may be punctured. In an embodiment, only a portion of the frozen bits may be used for differentiation of a control format.

FIG. 6 shows an example method of identifying a WTRU using a frozen bit of a polar code. A base station may determine the positions of frozen bits for a polar code 610. The positions of frozen bits may be determined, for example, from the process of polar code construction. The frozen bit positions may be referred to as fₖ where (k=0, 1, . . . , N−K−1). The frozen bit positions may be saved in a memory. The base station may determine the frozen bit positions by accessing the memory to retrieve the frozen bit positions.

The base station may determine a value for at least one frozen bit 620. The frozen bit values may be referred to as vₖ where (k=0, 1, . . . , N−K−1). The frozen bits values may be defined as vₖ=c_{i,k}.

The value of i may be a function of a WTRU ID, for example, a WTRU cell radio network temporary identifier (C-RNTI). A different frozen bit value may be used for each WTRU ID to differentiate between WTRUs. This may help to protect from a false detection between WTRUs and identify one WTRU from another WTRU. A WTRU group ID may be used instead of WTRU ID. A WTRU ID inclusion may be used for security purposes. A lower false alarm probability and no zero padding may be provided for a control channel design. A more secure communication may be expected between different WTRUs. In an embodiment, only a portion of the frozen bits may be used for a WTRU ID or a WTRU group ID.

A WTRU and a base station may be aware of the WTRU's ID or group ID. For example, a WTRU and a base station may become aware of the WTRU's C-RNTI during a random access channel (RACH) procedure. The base station may use the known WTRU ID or group ID as a frozen bit value.

The base station may send a polar coded transmission to a WTRU 630 using the determined frozen bit value. The WTRU may attempt to decode the polar coded transmission based on its assigned WTRU ID 640. On a condition that a value of a frozen bit of the polar coded transmission corresponds to the WTRU's ID, the WTRU knows that the transmission was intended for itself. On a condition that a value of the frozen bits does not correspond to the WTRUs ID, the WTRU knows that the transmission is not intended for itself.

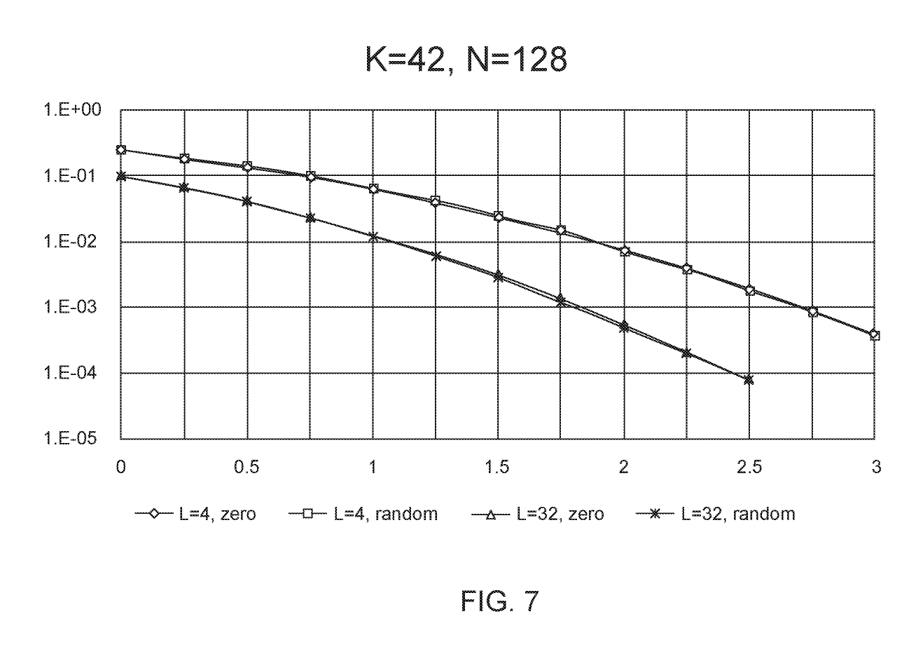

FIG. 7 shows numerical results using the following simulation conditions: (N,K,A)=(128,42,A) (R= 21/64); BPSK, AWGN, SCL+CRC decoder, L=4 or 32; 16 bit CRC; Bhattacharyya bounds code construction; AWGN; Design SNR=0 dB; x axis: E_{b}/N₀ (dB), y axis: FER. As shown in FIG. 7, there is no noticeable performance difference between using zero valued frozen bits and random valued frozen bits.

In decoding polar codes based on SCL, candidate selection by CRC detection provides a considerable gain over candidate selection by a best probability metric. A CRC may be attached to a data frame for error detection and the CRC may not be considered as an additional overhead.

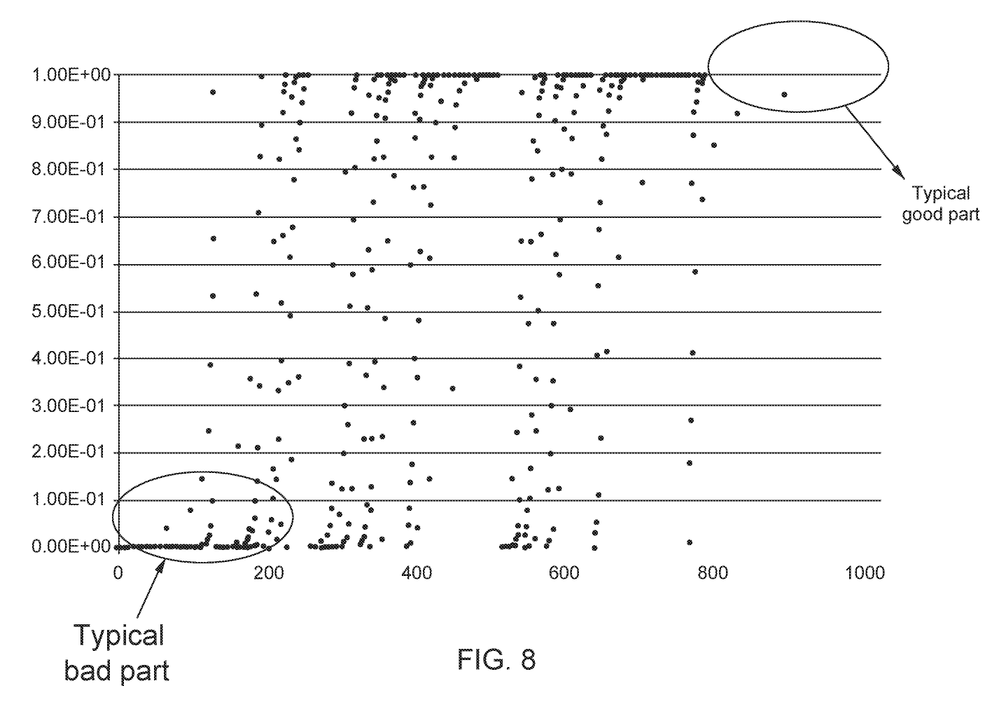

A CRC performs an important role in polar decoding. The most common rule for CRC position is to place it in the tail of an input block to the polar coder. This is similar as may be found in current LTE specifications. After CRC calculation for the total information bits, the final result is attached to the end. The tail part of the input bits of polar codes show a tendency of having good reliability, as shown in FIG. 8, where N=1024, but are randomly chosen in terms of reliability order. If we sort the unfrozen bits by reliability in increasing order, most of the tail CRC bits may be positioned in good parts The graph shown in FIG. 8 may be acquired from a code construction and assumes the following: x axis: input bit index from 0 (first input bit) to 1023 (last input bit); y axis: reliability from 0 (most unreliable) to 1 (most reliable).

A CRC is important to SCL decoding of polar codes. An allocation of good reliable bits to the CRC bits may cause a reduced reliability of the other input data bits. Thus, a balance of reliability between the CRC and the input data bits is needed.

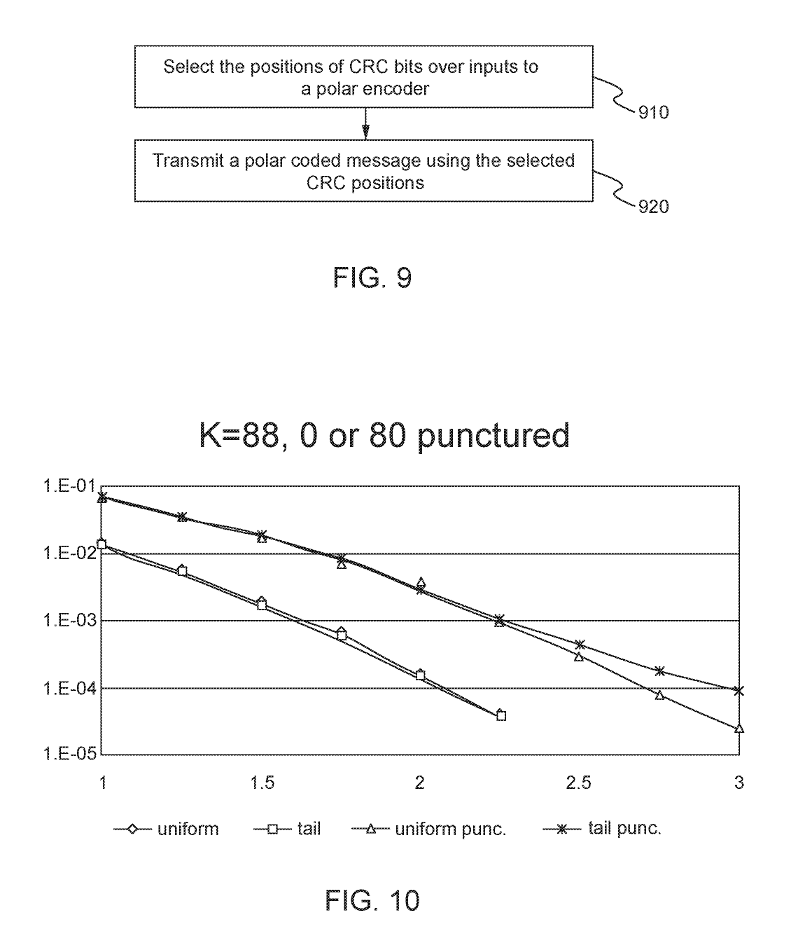

FIG. 9 shows an example method of using reliable blocks of a polar coded transport block to assign CRC bits. A base station may select positions of CRC bits over rₖ 910. The variable rₖ represents the position of inputs to a polar encoder and has a value from 0 to N−1. If rₖ (where k=0, 1, . . . , K−1) is the (K−1−k)^{th} most reliable input position, r_{K-1} is the most reliable and r₀ is the least reliable. The reliability of unfrozen bits may be determined, for example, from the process of polar code construction. The base station may store the reliabilities of unfrozen bits in a memory. The base station may sort the reliabilities of unfrozen bits. The base station may store the sorted reliabilities of unfrozen bits in the memory. The base station may retrieve the sorted reliabilities from the memory and use the sorted reliabilities in selecting the CRC positions.

The CRC positions may be selected uniformly over rₖ. If s is the length of the CRC, the positions may be selected as shown in Equation 2.

$${c}_{i} = ⌊ \frac{K}{s} \times i ⌋ + o \qquad Equation 2$$

where o is a offset and may have values from 0 to

$$⌊ \frac{K}{s} ⌋ - 1. {r}_{{c}_{0}} , … , {r}_{{c}_{s - 1}}$$

are chosen as CRC positions. The starting point of selection may be positioned from the end of the reliability order and the below positions may also be selected.

$${c}_{i} = K - 1 - ⌊ \frac{K}{s} \times i ⌋ - 0 \qquad Equation 3$$

The base station may transmit a polar coded message using the selected CRC positions 920. A WTRU may receive and decode the polar coded message.

In an embodiment, an interleaving scheme may be used to uniformly select the positions of CRC bits. One example is a bit reversing interleaver. Bit reversing may be performed on rₖ with a length of m (2^{m}=M>=K). The input index from 0 to M−1 is input to the bit reversing interleaver until a length s with proper output positions for a CRC are found. When the output index of the interleaver is larger than K−1, the output index may be pruned. Until a smaller value of K is found, the original input index to a bit reversing interleaver may be incremented. s of the output bits (e.g. s consecutive positions starting from any position) from the interleaver after interleaving of K input bits may be selected as CRC positions.

In an embodiment, a WCDMA downlink rate matching algorithm may be used to uniformly select the positions of CRC bits for K input information bits to find s CRC positions. The puncturing number or repetition number, as a parameter for rate matching, may be s and puncturing or repetition positions acquired from rate matching may be used for the CRC positions.

When the input block length is long enough, it may be difficult to find a difference in performance by changing the positions of the CRC bits. When the input block length is small and the ratio of the CRC length to the total block length is large enough, a difference in performance may be observed.

A puncturing algorithm disclosed by Wang and Liu in, “A Novel Puncturing Scheme for Polar Codes”, is known to show good performance. This puncturing algorithm must fix the values of bits to “0” from the end of the input bits. There are corresponding output bits to these fixed inputs and they are punctured. The position of the input bits have a relation of bit reversing to the output bits. These fixed value bits are similar to frozen bits and may include good reliable bits.

FIG. 10 shows a comparison between using a tail CRC and using the method as discussed in relation to FIG. 9 when K=88 with or without puncturing. The puncturing algorithm in FIG. 10 is based on the puncturing algorithm as disclosed by Wang and Liu.

The following simulation conditions are assumed: (N,K,A)=(256,88,A) (R= 11/32 or R=½, 80 bits punctured); BPSK, AWGN, SCL+CRC decoder, L=32; 16 bit CRC; Bhattacharyya bounds code construction; AWGN; design SNR=0 dB; x axis: E_{b}/N₀ (dB), y axis: FER. There is no remarkable difference observed between the two schemes without puncturing. The puncturing of 80 bits and a 16 bit tail CRC causes a lack of good reliable bits for the information input bits and a degradation of performance is observed. A performance difference of about 0.25 dB at a FER of 10⁻⁴ is observed.

The puncturing pattern disclosed by Wang and Liu in “A Novel Puncturing Scheme for Polar Codes,” (hereinafter referred to as “schemeA”) shows better performance than Quasi-Uniform Puncturing (QUP) and does not require additional code construction. When P is the number of puncturing bits, schemeA may be described as follows. Puncture the position of output bits numbered as BR(N−1−i), i=0, 1, . . . , P−1. Fix the values in the position of input bits numbered N−1−i to zero, i=0, 1, . . . , P−1. BR( ) is the bit reversing function for a length of n(N=2ⁿ) bit. For example, BR(2)=BR(0010₂)=0100₂=4 for a length of 4 bit. The output bits in polar codes have a relation of bit reversing with the input bits. The corresponding input bits to punctured output bits should be fixed to a zero value as in schemeA. Thus, the input bits are fixed to zero from the end of input bits by schemeA.

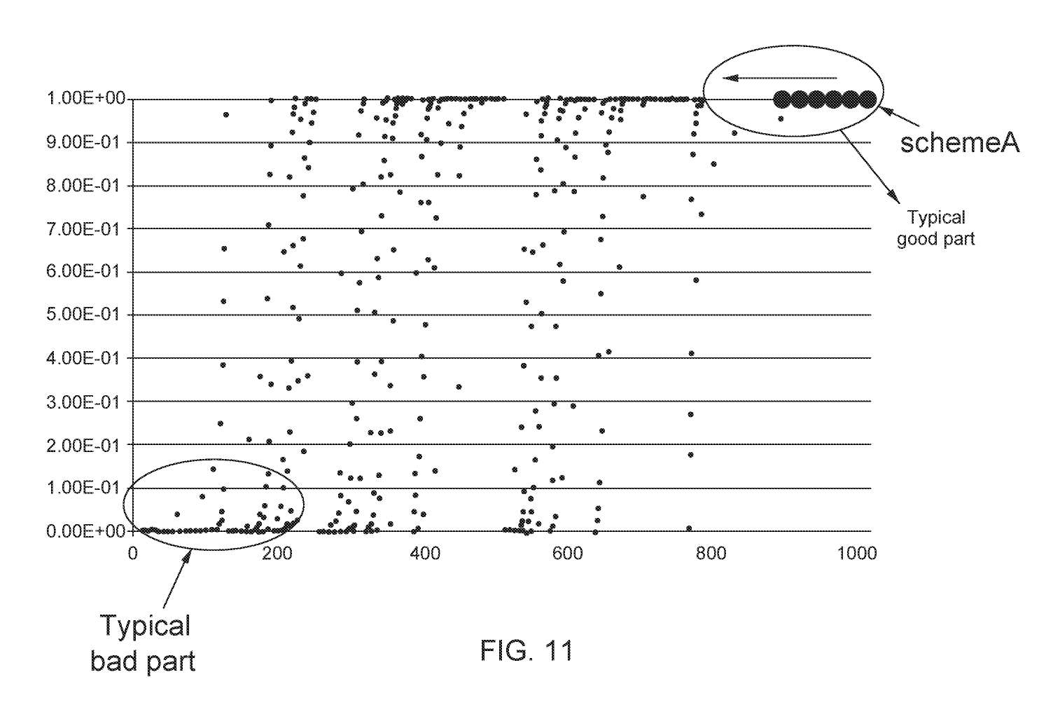

FIG. 11 shows a distribution of reliabilities of polar codes. Typically the ending portion of the input bits of a polar code has good reliability. Scheme A may make the good reliability bits fixed or frozen. When a code rate is low, the number of bits with good reliability is limited, and schemeA may give a bad influence on puncturing performance by fixing values of input bits to zero from the end serially.

If the fixed input bits are positioned in a distributive manner, performance may be improved. One thing that should be noted regarding the necessity of puncturing for low rate polar codes is that it is essentially needed to acquire a specific code rate of some input block sizes for binary based polar codes. For example, if a code rate of ⅖ with input block size of 256 is used, there is usually no way except puncturing from a code rate of ¼ with output block size of 1024. If an input block size is less than 256, we may have a code rate of ⅖ with output block size of 512. For example, when the input block size is 176, we can have the code rate of ⅖ by puncturing 72 bits from (512, 176, A) polar codes.

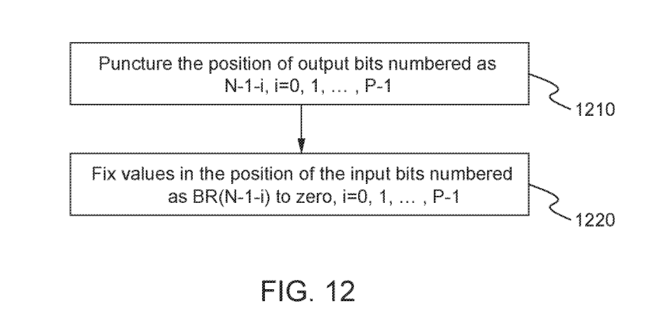

FIG. 12 shows an example method of puncturing for low code rate polar codes. A base station and/or a WTRU may puncture the position of output bits numbered as N−1−i, i=0, 1, . . . , P−1 (1210). The base station and/or WTRU may fix values in the position of the input bits numbered as BR(N−1−i) to zero, i=0, 1, . . . , P−1 (1220).

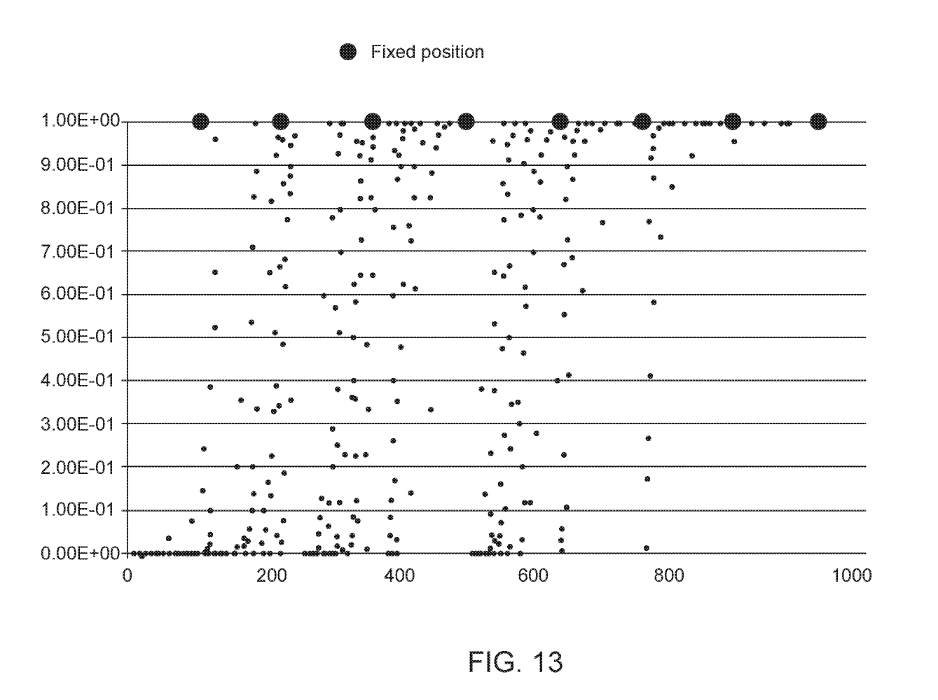

Considering the relation between input and output bits, serial puncturing of the output bits from the end corresponds to fixed zero values in the input bits with a pattern of ‘quasi-uniform’. For example, if eight bits are punctured according to the method as discussed above with reference to FIG. 12, the fixed values of input bits may be seen as shown in FIG. 13 and distributed over all input bits with less fixing of the ending part as compared to schemeA.

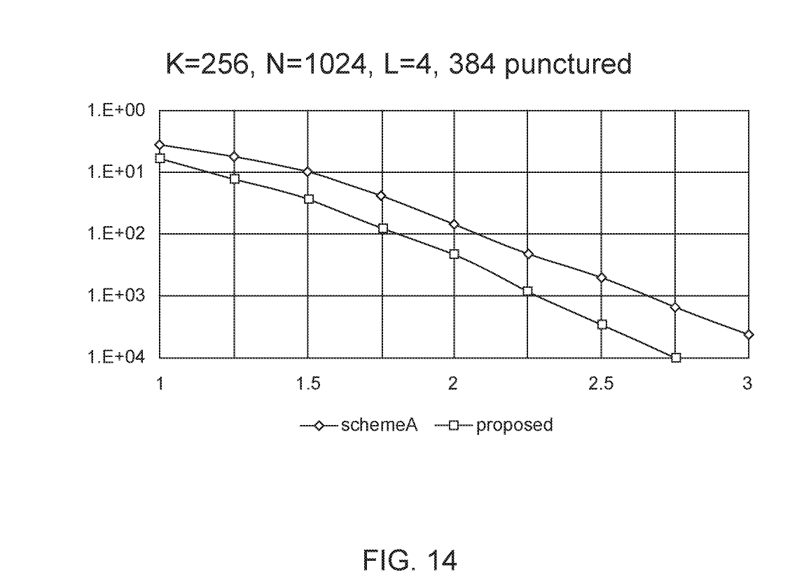

FIG. 14 shows a performance comparison between schemeA and the method as discussed above with reference to FIG. 12 and assumes the following simulation conditions: (N,K,A)=(1024,256,A) (R=¼) before puncturing; BPSK, AWGN, SCL+CRC decoder; L=4, 3GPP LTE 16 bit CRC; Bhattacharyya bounds code construction; AWGN; design SNR=0 dB; 384 punctured->(640,256) (R=⅖); x axis: E_{b}/N₀ (dB), y axis: FER. An approximate 0.4 dB gain may be observed at a FER of 10⁻³.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, or any host computer.

1. A method for transmitting a polar coded transport block, implemented by a base station, the method comprising:
determining a position of a frozen bit of a polar code;
determining a value for the frozen bit, wherein the value for the frozen bit is based on a wireless transmit/receive unit's (WTRU's) identity (ID); and
transmitting a polar coded transport block to the WTRU that includes the frozen bit value that is based on the WTRU's ID.

2. The method of claim 1, wherein the position of the frozen bit is determined from polar code construction.

3. The method of claim 1, further comprising:
representing a k^{th} frozen input position for n=0 to N−K−1 using fₖ and representing values of the frozen bits for n=0 to N−K−1 using vₖ.

4. The method of claim 3, wherein a vₖ is defined for each one of a plurality WTRU IDs, wherein vₖ=c_{i,k}.

5. The method of claim 4, wherein on a condition that a size of the frozen bits and c_{i,k} are different, c_{i,k} is punctured.

6. The method of claim 4, wherein a value of i is a function of a WTRU ID.

7. The method of claim 6, wherein the WTRU ID is a cell radio network temporary identifier (C-RNTI).

8. The method of claim 6, wherein the WTRU ID is a group ID.

9. The method of claim 1 wherein the WTRU decodes the polar coded transport block on a condition a frozen bit value is associated with the WTRUs ID.

10. A base station comprising:
at least one processor configured to determine a position of a frozen bit of a polar code;
the at least one processor configured to determine a value for the frozen bit, wherein the value for the frozen bit is based on a wireless transmit/receive unit's (WTRU's) identity (ID); and
a transmitter configured to transmit a polar coded transport block to the WTRU that includes the frozen bit value that is based on the WTRU's ID.

11. The base station of claim 10, wherein the position of the frozen bit is determined from polar code construction.

12. The base station of claim 10, further comprising:
the at least one processor configured to represent a k^{th} frozen input position for n=0 to N−K−1 using fₖ and to represent values of the frozen bits for n=0 to N−K−1 using vₖ.

13. The base station of claim 12, wherein a vₖ is defined for each one of a plurality WTRU IDs, wherein vₖ=c_{i,k}.

14. The base station of claim 13, wherein on a condition that a size of the frozen bits and c_{i,k} are different, c_{i,k} is punctured.

15. The base station of claim 13, wherein a value of i is a function of a WTRU ID.

16. The base station of claim 15, wherein the WTRU ID is a cell radio network temporary identifier (C-RNTI).

17. The base station of claim 15, wherein the WTRU ID is a group ID.

18. The base station of claim 10 wherein the WTRU decodes the polar coded transport block on a condition a frozen bit value is associated with the WTRUs ID.

19. A method for differentiating between control formats, implemented by a base station, the method comprising:
determining a position for a frozen bit of a polar code;
determining a control format;
determining a value for the frozen bit, wherein the value for the frozen bit is a function of the determined control format; and
transmitting a polar coded message including control format information using the determined frozen bit value.
